(19) United States
(12) Patent Application Publication
(10) Pub. No.: US 2025/0023452 A1
(43) Pub. Date: Jan. 16, 2025

(54) POWER CHIP AND BRIDGE CIRCUIT

(71) Applicant: Delta Electronics (Shanghai) CO., LTD., Shanghai (CN)

(72) Inventors: Xiaoni XIN, Shanghai (CN); Le LIANG, Shanghai (CN)

(73) Assignee: Delta Electronics (Shanghai) CO., LTD., Shanghai (CN)

(21) Appl. No.: 18/896,986

(22) Filed: Sep. 26, 2024

Related U.S. Application Data
(63) Continuation of application No. 17/030,604, filed on Sep. 24, 2020, now abandoned.
Application No. 17/030,604 is a continuation-in-part of application No. 15/613,424, filed on Jun. 5, 2017, now Pat. No. 10,826,483.

(30) Foreign Application Priority Data
Aug. 26, 2016 (CN) 201610744165.9

(51) Int. Cl. H02M 1/088; H01L 27/00; H01L 27/12; H01L 29/00; H01L 29/24; H01L 29/74; H01L 29/749; H02M 1/00; H02M 3/158

(52) U.S. Cl. CPC H02M 1/088; H01L 27/1225; H01L 29/242; H01L 29/7428; H01L 29/749; H02M 3/158; H01L 27/00; H01L 29/00; H01L 2924/1067; H02M 1/0048

(57) ABSTRACT

A power chip, includes a metal region; a wafer region. The wafer region includes at least one first partition, forming a first power switch; and at least one second partition, forming a second power switch. The first power switch and the second power switch are electrically connected, a total number of the at least one first partition and the at least one second partition is not less than 3, and the at least one first partition and the at least one second partition are disposed alternatively along a curve.

### CROSS REFERENCE

This application is a continuation of U.S. application Ser. No. 17/030,604, which is a CIP of U.S. application Ser. No. 15/613,424 claiming priority to Chinese Patent Application No. 201610744165.9. The entire contents of the forgoing applications are incorporated herein by reference.

### TECHNICAL FIELD

The present disclosure relates to a power chip and a bridge circuit, and more particularly, to a power chip and a bridge circuit which may reduce a parasitic inductance.

### BACKGROUND

With growth of people's demand for an intelligent lifestyle, demand for data processing is also growing. The global energy consumption in data processing has reached about hundreds of billions of or even trillions of kilowatts-hour each year, and a large data center can occupy an area up to tens of thousands of square meters. Accordingly, high efficiency and high power density are significant indicators of a healthy development of the data center industry.

A critical unit of the data center is a server, which is typically equipped with a mainboard composed of data processing chips (such as a CPU, chipsets, a memory or the like), power supplies thereof and necessary peripheral components. With increase of the processing capacity of a server, the number and the integration of the processing chips are also increasing, resulting in enlargement of the occupied space and increase of power consumption. Accordingly, the power supply (also referred to as a mainboard power supply since it is on the same mainboard as the data processing chips) for the chips is expected to have higher efficiency, higher power density and smaller volume, which is conducive to the energy saving and reduction of the occupied resource for the entire server or even of the entire data center.

### SUMMARY

According to an aspect of the present disclosure, there is provided a power chip, including: a metal region; a wafer region including: at least one first partition, forming a first power switch; and at least one second partition, forming a second power switch, wherein the first power switch and the second power switch are electrically connected, a total number of the at least one first partition and the at least one second partition is not less than 3, and the at least one first partition and the at least one second partition are disposed alternatively along a curve.

According to an embodiment of the present disclosure, the first power switch has a first terminal, a second terminal and a control terminal, the second power switch has a first terminal, a second terminal and a control terminal, and that the first power switch is electrically connected to the second power switch, includes any one of: that the first terminal of the first power switch is electrically connected to the first terminal of the second power switch, that the second terminal of the first power switch is electrically connected to the second terminal of the second power switch, and that the second terminal of the first power switch is electrically connected to the first terminal of the second power switch.

According to an embodiment of the present disclosure, the curve is one of: a closed loop and an open curve, the close loop is any one of: a polygon and an oval; and the open curve is any one of: a straight line, a polyline and an arc.

According to an embodiment of the present disclosure, the second terminal of the first power switch is electrically connected to the first terminal of the second power switch, the power chip further including: a capacitor, disposed in the metal region, wherein the capacitor, the first power switch and the second power switch form a commutation circuit loop.

According to an embodiment of the present disclosure, the metal region includes: a first wiring layer, located above the wafer region, and configured to form a first pin through a metal lead; and a second wiring layer, located above or below the first wiring layer, and configured to form a second pin through a metal lead, wherein the capacitor is formed between the first wiring layer and the second wiring layer by an anode oxidation process.

According to an embodiment of the present disclosure, the second terminal of the first power switch is electrically connected to the first terminal of the second power switch, the power chip further including: a capacitor, disposed in the wafer region, wherein the capacitor, the first power switch and the second power switch form a commutation circuit loop.

According to an embodiment of the present disclosure, the wafer region includes: a N type insulating layer, disposed between a P type substrate layer and the at least one first partition and the at least one second partition, and two ends of a junction capacitor between the N type insulating layer and the P type substrate layer are respectively coupled to a first pin and a second pin through metal leads.

According to an embodiment of the present disclosure, the N type insulating layer is coupled to the second pin through a wire electrode N+, and the P type substrate layer is coupled to the first pin through a wire electrode P+.

According to an embodiment of the present disclosure, the power chip further includes: at least one first driving circuit, wherein one of the at least one first driving circuit is configured to be closely adjacent to one of the at least one first partition; and at least one second driving circuit, wherein one of the at least one second driving circuit is configured to be closely adjacent to one of the at least one second partition.

According to an embodiment of the present disclosure, the power chip further includes: at least one first driving circuit, wherein each of the at least one first driving circuit is configured to be closely adjacent to a corresponding one of the at least one first partition; and at least one second driving circuit, wherein each of the at least one second driving circuit is configured to be closely adjacent to a corresponding one of the at least one second partition, wherein the first driving circuit and the second driving circuit are disposed alternatively to correspond to the alternative arrangement of the first and second partitions.

According to an embodiment of the present disclosure, one of the at least one first driving circuit is disposed surrounding or partially surrounding the one of the at least one first partition and the second driving circuits is disposed surrounding or partially surrounding the one of the at least one second partition.

According to an embodiment of the present disclosure, each of the at least one first driving circuit is disposed surrounding or partially surrounding the corresponding one of the at least one first partition and the second driving circuits is disposed surrounding or partially surrounding the corresponding one of the at least one second partition.

According to an embodiment of the present disclosure, a shape of each of the at least one first partition and the at least one second partition is rectangle, the curve is a rectangle, and the numbers of the at least one first partition and the at least one second partition are both two.

According to an embodiment of the present disclosure, a shape of each of the at least one first partition and the at least one second partition is the same type of polygon, the at least one first driving circuit and the at least one second driving circuit are disposed at one side of the at least one first partition and one side of the at least one second partition respectively.

According to an embodiment of the present disclosure, a shape of each of the at least one first partition and the at least one second partition is rectangle, each of the at least one first partition and the at least one second partition has a first side, a second side, a third side and a fourth side, and the first side, the second side, the third side and the fourth side of the at least one first partition are corresponding to the first side, the second side, the third side and the fourth side of the at least one second partition respectively.

According to an embodiment of the present disclosure, the numbers of the at least one first partition and the at least one second partition are both two, the numbers of the at least one first driving circuit and the at least one second driving circuit are both two, and the curve is a rectangle.

According to an embodiment of the present disclosure, the at least one first driving circuit and the at least one second driving circuit are disposed at one side of the at least one first partition and one side of the at least one second partition respectively.

According to an embodiment of the present disclosure, one of the at least one first driving circuit is positioned at the first side of the corresponding one of the at least one first partition, the other one of the at least one first driving circuit is positioned at the third side of the corresponding one of the at least one first partition, one of the at least one second driving circuit is positioned at the first side of the corresponding one of the at least one second partition, and the other one of the at least one second driving circuit is positioned at the third side of the corresponding one of the at least one second partition.

According to an embodiment of the present disclosure, one of the at least one first driving circuit is positioned at the fourth side of the corresponding one of the at least one first partition, the other one of the at least one first driving circuit is positioned at the second side of the corresponding one of the at least one first partition, one of the at least one second driving circuit is positioned at the second side of the corresponding one of the at least one second partition, and the other one of the at least one second driving circuit is positioned at the fourth side of the corresponding one of the at least one second partition.

According to an embodiment of the present disclosure, each of the at least one first driving circuit is positioned at two adjacent sides of the corresponding one of the at least one first partition, and each of the at least one second driving circuit is positioned at two adjacent sides of the corresponding one of the at least one second partition.

According to an embodiment of the present disclosure, one of the at least one first driving circuit is positioned at the first side and the second side of the corresponding one of the at least one first partition, one of the at least one first driving circuit is positioned at the third side and the fourth side of the corresponding one of the at least one first partition, one of the at least one second driving circuit is positioned at the second side and the third side of the corresponding one of the at least one second partition, and one of the at least one second driving circuit is positioned at the first side and the fourth side of the corresponding one of the at least one second partition.

According to an embodiment of the present disclosure, each of the at least one first driving circuit is positioned at two opposite sides of the corresponding one of the at least one first partition, and each of the at least one second driving circuit is positioned at two opposite sides of the corresponding one of the at least one second partition.

According to an embodiment of the present disclosure, one of the at least one first driving circuit is positioned at the third side of the corresponding one of the at least one first partition, one of the at least one first driving circuit is positioned at the first side of the corresponding one of the at least one first partition, each of the at least one second driving circuit is positioned at the first side and the third side of the corresponding one of the at least one second partition.

According to an embodiment of the present disclosure, each of the at least one first driving circuit is positioned at three sides of the corresponding one of the at least one first partition, and each of the at least one second driving circuit is positioned at three sides of the corresponding one of the at least one second partition.

According to an embodiment of the present disclosure, each of the at least one first driving circuit is disposed partially surrounding the corresponding one of the at least one first partition and the second driving circuits is disposed partially surrounding the corresponding one of the at least one second partition.

According to an embodiment of the present disclosure, each of the at least one first driving circuit is disposed at two adjacent sides of the corresponding one of the at least one first partition and the second driving circuits is disposed at two adjacent sides of the corresponding one of the at least one second partition.

According to an embodiment of the present disclosure, the two adjacent sides are continuous.

According to an embodiment of the present disclosure, the two adjacent sides are not continuous.

According to an embodiment of the present disclosure, a first one of the at least one first partition, a first one of the at least one second partition and a second one of the at least one first partition are arranged along a Y direction, a third one of the at least one first partition, a second one of the at least one second partition and a fourth one of the at least one first partition are arranged along a Y direction, the first one of at least one first partition and the third one of at least one first partition are arranged along a X direction, the first one of at least one second partition and the second one of at least one second partition are arranged along a X direction, the second one of at least one first partition and the fourth one of at least one first partition are arranged along a X direction, one of the at least one first driving circuit is T-shape and located at two sides of the first one of the at least one first partition and the third one of the at least one first partition, another one of the at least one first driving circuit is T-shape and located at two sides of the second one of the at least one first partition and the fourth one of the at least one first partition, and one of the at least second driving circuit is H-shape and partially surrounds the first one of the at least one second partition and the second one of the at least one second partition.

According to an embodiment of the present disclosure, both the first driving circuit and the second driving circuit further include a driving capacitor.

According to an aspect of the present disclosure, there is provided a bridge circuit for reducing parasitic inductance, including:
a first power switch, forming a first bridge arm of the bridge circuit, wherein the first bridge arm has a first terminal and a second terminal;
a second power switch, forming a second bridge arm of the bridge circuit, wherein the second bridge arm is coupled with the first bridge arm in series and has a first terminal and a second terminal, and the first terminal of the second bridge arm is electrically coupled to the second terminal of the first bridge arm; and
a capacitor, having a first end and a second end, wherein the first end of the capacitor is electrically coupled to the first terminal of the first bridge arm, and the second end of the capacitor is electrically coupled to the second terminal of the second bridge arm,
wherein at least one of the first bridge arm and the second bridge arm includes two or more power switches which are coupled in parallel with each other, the first and second power switches are integrated in a power chip, and the first and second power switches are arranged alternatively along at least one direction inside the power chip.

### BRIEF DESCRIPTION OF THE DRAWINGS

FIG. 1 is a schematic diagram of a circuit architecture of a low voltage Buck circuit converting 5V to 1.8V;

FIG. 2 is a schematic diagram of a loss percentage change of the power device depending on change of frequency in the Buck circuit;

FIG. 3 is a schematic diagram of a bridge Buck circuit;

FIG. 4 is a schematic diagram of a voltage spike change across the power switch when the power switch in the bridge Buck circuit is turned off;

FIG. 5 is a schematic diagram of parasitic inductance and switch loss at different switch frequencies in the bridge Buck circuit;

FIG. 6 is a schematic diagram of the first and second partitions being separately arranged in a power chip;

FIG. 7 is a top view showing the partitions arranged alternatively in a power chip according to an embodiment of the present disclosure;

FIG. 8 is a top view showing the partitions arranged alternatively in a power chip according to another embodiment of the present disclosure;

FIG. 9 is a top view showing an arrangement of the partitions in a power chip according to another embodiment of the present disclosure;

FIG. 9a is a schematic plan diagram showing an arrangement of the partitions in a power chip according to another embodiment of the present disclosure;

FIG. 9b is a schematic plan diagram showing an arrangement of the partitions in a power chip according to another embodiment of the present disclosure;

FIG. 9c is a schematic plan diagram showing an arrangement of the partitions in a power chip according to another embodiment of the present disclosure;

FIG. 9d is a schematic plan diagram showing an arrangement of the partitions in a power chip according to another embodiment of the present disclosure;

FIG. 9e is a schematic plan diagram showing an arrangement of the partitions in a power chip according to another embodiment of the present disclosure;

FIG. 9f is a schematic plan diagram showing an arrangement of the partitions in a power chip according to another embodiment of the present disclosure;

FIG. 10 is a sectional view showing a power chip according to an embodiment;

FIG. 11 is a sectional view showing a power chip in which a capacitor is provided in a metal region according to an embodiment;

FIG. 12 is a sectional view showing a metal region of a power chip;

FIG. 13 is a sectional view showing a power chip according to another embodiment;

FIGS. 14a-14b and FIGS. 15a-15c are top view showing an arrangement of wire electrodes in a power chip;

FIG. 16 is a top view showing a power chip according to another embodiment of the present disclosure;

FIG. 16a is a schematic plan diagram showing an arrangement of the partitions in a power chip according to another embodiment of the present disclosure;

FIG. 16b is a schematic plan diagram showing an arrangement of the partitions in a power chip according to another embodiment of the present disclosure;

FIG. 16c is a schematic plan diagram showing another example wherein the first and second driving circuits partially surround the corresponding partitions T1 and T2;

FIG. 16d is a schematic plan diagram showing another example wherein the first and second driving circuits partially surround the corresponding partitions T1 and T2;

FIG. 16e is a schematic plan diagram showing another example wherein the first and second driving circuits partially surround the corresponding partitions T1 and T2;

FIG. 17 is a perspective view showing a power chip according to another embodiment of the present disclosure;

FIG. 18 is a schematic circuit showing a driving circuit in a power chip according to an embodiment of the present disclosure; and

FIG. 19 is a schematic circuit showing a driving circuit in a power chip according to another embodiment of the present disclosure.

### DETAILED DESCRIPTION

A number of different embodiments or examples are provided below, which are used to implement various features of the present disclosure. The following is a specific embodiment or example which discloses various elements and arrangements, to simplify description of the present disclosure. Of course, these are only examples, but not limited thereto. For example, in the description, a structure in which the first feature is located above the second feature may include a form that the first feature contacts directly with the second feature, and it may also include a form that an additional feature is inserted between the first feature and the second feature, such that the first feature and the second feature do not directly contact with each other. In addition, reference numerals and/or characters will be repeated in various examples of the present disclosure. The foregoing repetition is for the purpose of simplification and clarity, and not intended to specify relationships in various embodiments and/or configurations.

In addition, spatially related terms, such as “underlying”, “below”, “lower”, “overlying”, “upper”, or the like are used herein to describe the relationship between one element or feature and another element or feature exemplified in the figures. The spatially related terms may include different orientations of the device in use or operation other than the orientation depicted in the figures. The device may be oriented (rotated 90 degrees or in other orientations) in other ways, and the spatially related descriptors used herein should be understood accordingly.

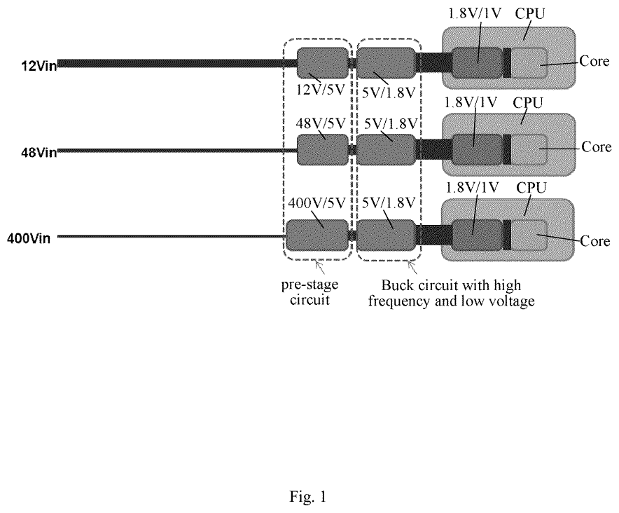

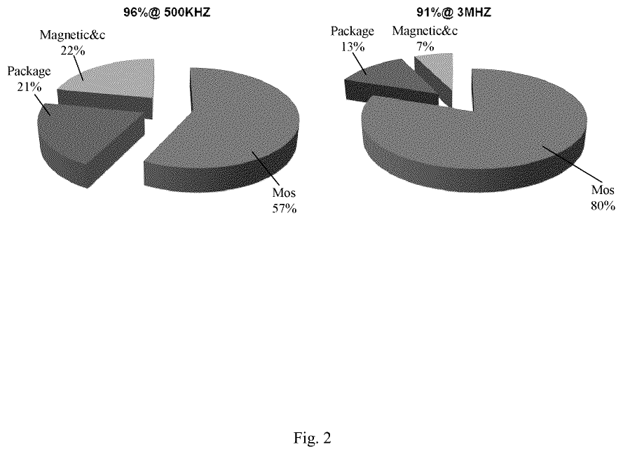

In order to increase power density, for circuit architecture as shown in FIG. 1, there is a potential demand for a low voltage BUCK circuit (5V to 1.8V) to continuously increase work frequency. Meanwhile, high frequency may also improve dynamic response speed for a CPU load change. However, as shown in FIG. 2, it can be seen that, after arriving at high frequency, loss proportion of a power device MOS greatly increases, which becomes the main bottleneck of a high efficiency target.

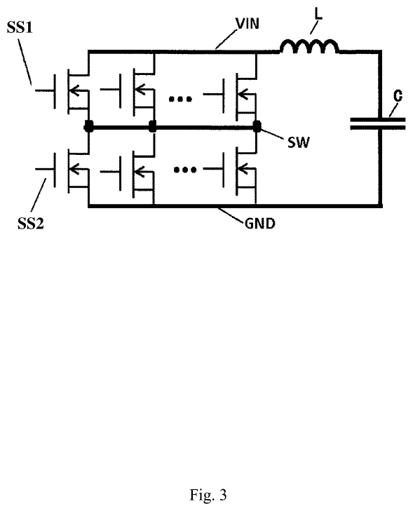

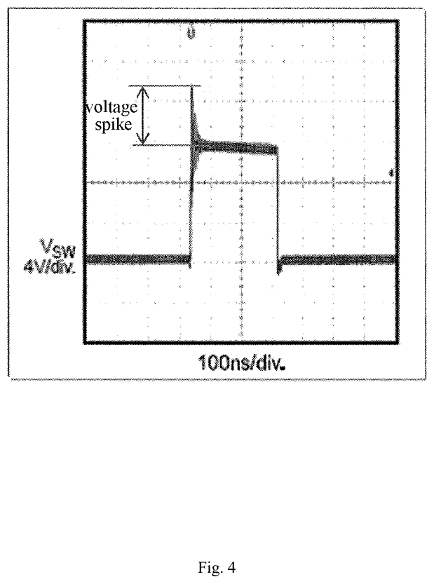

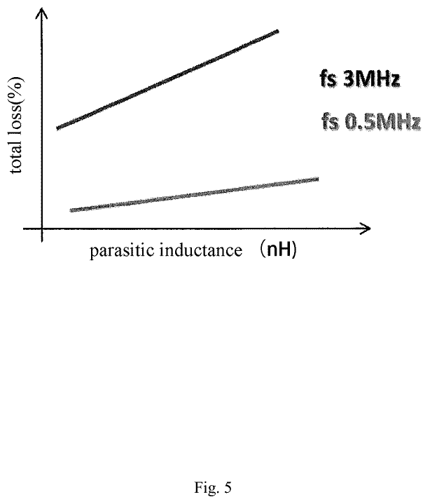

Efficiency of the Buck circuit is related to the parasitic inductance of a commutation circuit loop. As shown in FIG. 3, an input capacitor C, first power switches SS1 and second power switches SS2 form a close-loop commutation circuit, wherein the first power switches SS1 include lots of switches connected in parallel to form an upper bridge arm, and the second power switches SS2 include lots of switches connected parallel to form a lower bridge arm. The commutation circuit may present a certain parasitic inductance value at the moment that the first power switch is turned on or turned off. The equivalent position of the parasitic inductor in the commutation circuit is shown in FIG. 3. The smaller the parasitic inductance L of the commutation circuit is, the higher the efficiency of the Buck circuit will be, which is reflected in the following two aspects: 1) the smaller the parasitic inductance is, the smaller the voltage spike at two ends of the power switch when being turned off is, so a power switch with better performance and lower voltage may be employed, thus increasing efficiency of the Buck circuit, as shown in FIG. 4) The smaller the parasitic inductance is, the smaller the switching loss is, thus increasing efficiency of the Buck circuit, as qualitatively shown in FIG. 5. When the switching frequency is higher, the parasitic inductance has more significant influence on the efficiency.

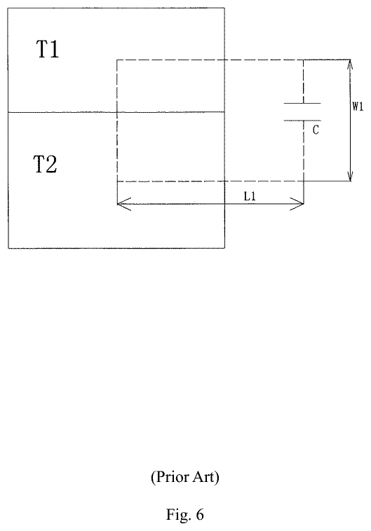

It can be seen that, in order to increase efficiency of the Buck circuit with high frequency and low voltage, it is important to reduce the parasitic inductance of the commutation circuit. In existing integrated chips, a monolithic chip is separated into two regions: the first partition T1 and the second partition T2, wherein the first power partition T1 forms the first power switches SS1 and the second partition T2 forms the second power switches SS2, as shown in FIG. 6. In this case, a size of the equivalent high frequency commutation circuit loop is related to a geometrical center distance W1 between the first and second partitions T1 and T2 and a distance L1 between geometrical centers of the first and second partitions T1 and T2 and the input capacitor C. An area of the commutation circuit loop is W1*L1, which approximately equals to a quarter of an area of the power chip. Thus, the size of the high frequency commutation circuit loop is affected by the area of the power chip. On the other hand, the area of the power chip is determined by an optimal design under multiple factors considered, such as a power load and an optimal efficiency point, such that it is difficult to simultaneously reduce the size of the high frequency commutation circuit loop, which has a degree of inflexibility.

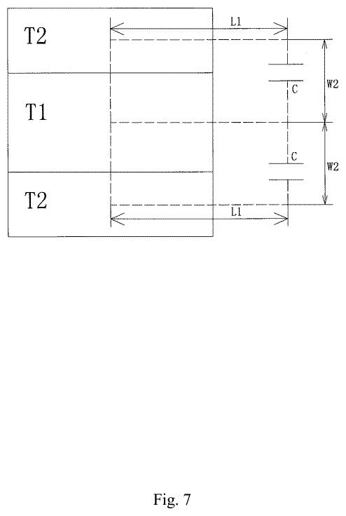

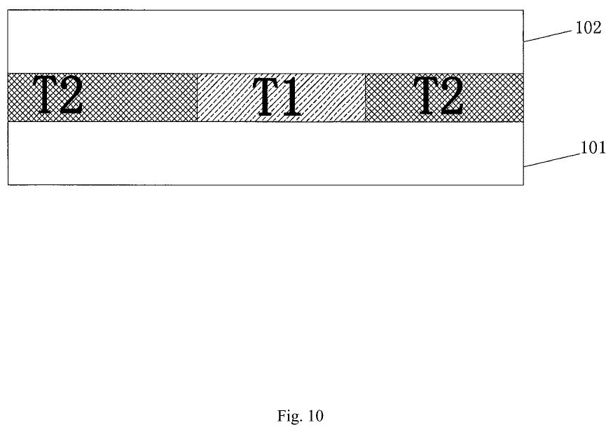

FIG. 7 is a top view showing an arrangement of the power switches in a power chip according to an embodiment of the present disclosure. As shown in FIG. 7 and FIG. 10, the power chip 10 includes a wafer region 101 and a metal region 102. The first and second partitions T1 and T2 are integrated in the wafer region 101.

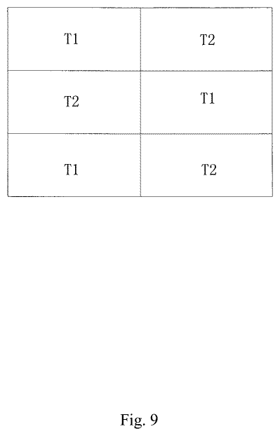

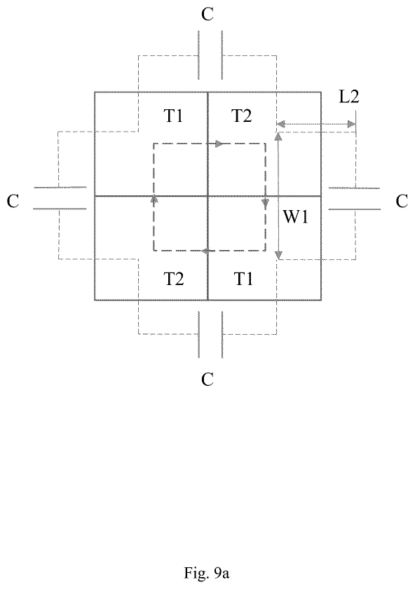

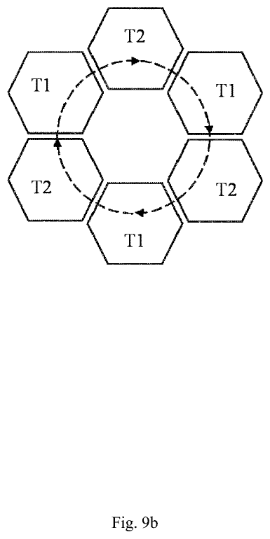

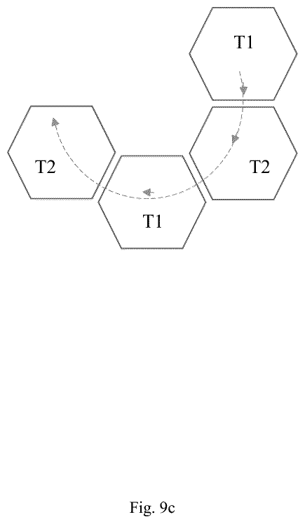

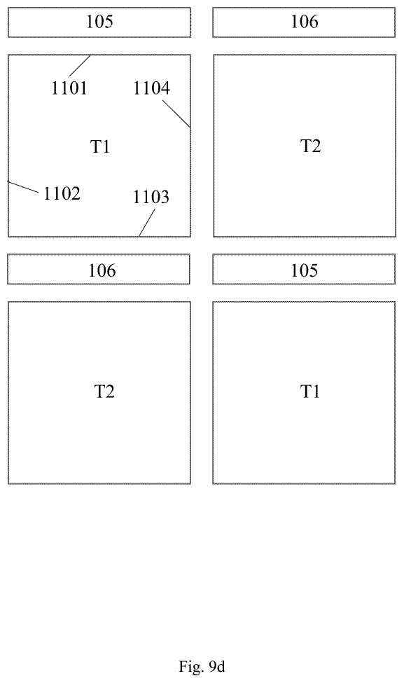

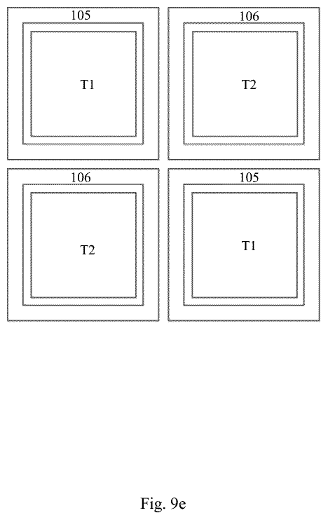

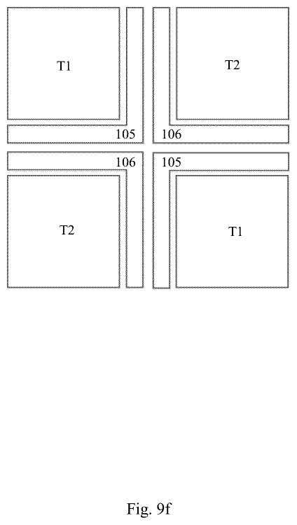

In FIG. 7, the power chip is separated into three regions: two partitions T2 and one partition T1, wherein partition T1 is used as an upper bridge arm and two partitions T2 are connected in parallel and used as a lower bridge arm of a bridge circuit or T1 is used as the lower bridge arm and two partitions T2 are connected in parallel and used as the upper bridge arm. In a structure, the first partitions T1 and the second partitions T2 may be disposed along at least one direction. For example, the first and second partitions T1 and T2 may be arranged alternatively along a Y direction (a vertical direction) in FIG. 7. The arrangements of the first and second partitions T1 and T2 are not limited thereto. For example, the first and second partitions T1 and T2 may also be arranged alternatively along an X direction (a horizontal direction), or arranged alternatively along the X and Y directions as shown in FIG. 9. The numbers of partitions T1 or T2 are not limited thereto. There may be more partitions T1 and T2 alternatively arranged along X direction or/and Y direction. In the embodiment, the first partition T1, the second partition T2 and a capacitor C outside the power chip 10 are coupled to form a commutation circuit loop. The equivalent circuit is shown as FIG. 3. A region size of the commutation circuit loop is S2=W2*L1, wherein W2 represents a distance between geometrical centers of the first and second power partitions T1 and T2, and L1 represents a distance between the geometrical centers of the partitions and the capacitor C.

Under the same area of the power chip, compared with the case as shown in FIG. 6 where one monolithic chip has two partitions, the case in the present embodiment where one monolithic chip has at least three partitions which are arranged alternatively may reduce the distance between the geometrical centers of the adjacent first and second partitions, i.e. W2<W1. When the distance L1 between the geometrical centers of the partitions and the capacitor is the same, the area of the commutation circuit loop correspondingly decreases, thus reducing the size of the commutation circuit loop, weakening the influence of the parasitic inductance, and improving efficiency of the power chip. In the present embodiment, the first and second partitions T1 and T2 are arranged alternatively for once, however, the times that the first and second partitions are arranged alternatively may vary depending on actual requirements. The more times the first and second partitions are arranged alternatively, the smaller the distance of the geometrical centers between the first and second partitions will be. The commutation circuit loop will be reduced correspondingly, which may further improve efficiency of the power chip.

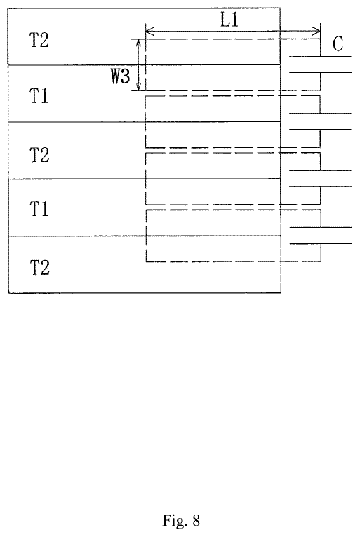

FIG. 8 is a schematic plan diagram showing an arrangement of the partitions in a power chip according to another embodiment of the present disclosure. The partitions in FIG. 8 are more than that in FIG. 7. In the present embodiment, the chip is separated into five regions: two first partitions (T1) and three second partitions (T2). The first and second partitions are arranged alternatively for twice. Under the same area of the power chip, the distance W3 between the geometrical centers of the first and second partitions in the present embodiment is smaller than W2, i.e. W3<W2, thus, the commutation circuit loop is smaller.

FIG. 9 is a schematic plan diagram showing an arrangement of the partitions in a power chip according to another embodiment of the present disclosure. Compared with the case as shown in FIGS. 7 and 8 where the first and second partitions are arranged alternatively along one direction, the first and second partitions in the present embodiment may be arranged alternatively along the X and Y directions.

The arrangement of the partitions in a power chip of the present disclosure is not limited to be disposed alternatively only along the X and/or Y directions.

As an embodiment, the present disclosure further provides a power chip, including a metal region and a wafer region. The wafer region includes at least one first partition T1 and at least one second partition T2, wherein a total number of the first partition and the second partition is not less than 3. That is to say, the number of T1 or T2 is larger than 1. All the first partitions T1 are connected in parallel as the first switch SS1 in FIG. 3; all the second partitions T2 are connected in parallel as the second switch SS2 in FIG. 3. The first partitions and the second partitions are disposed alternatively along a curve.

The power switches of the present disclosure can be any type of switch device, such as MOSFET, IGBT, or the like. As an embodiment, in the power chip, both of the first power switch and the second power switch have a first terminal, a second terminal and a control terminal. As shown in FIG. 3, the second terminal of the first power switch is connected to the first terminal of the second power switch so that a bridge is formed.

Actually, the first terminal of the first power switch may electrically connected to the first terminal of the second power switch, or the second terminal of the first power switch may electrically connected to the second terminal of the second power switch.

If the first power switch and the second power switch are MOSFETs, the first terminal is source electrode, the second terminal is drain electrode, and a control terminal is gate electrode.

If the first power switch and the second power switch are IGBTs, the first terminal is emitter electrode, the second terminal is collector electrode, and a control terminal is gate electrode.

The curve here means a continuous line which may refer to a closed loop or an open curve, wherein the closed loop may be any one of: a polygon and an oval, etc.; and the open curve may be any one of: a straight line, a polyline and an arc, etc.

Further, in the present disclosure, that the first partitions and the second partitions are disposed alternatively means that one second partition is between two first partitions and/or one first partition is between two second partitions.

FIG. 9a is a schematic plan diagram showing an arrangement of the partitions in a power chip according to another embodiment of the present disclosure. In the present embodiment, the first partitions T1 and the second partitions T2 are disposed alternatively along a curve, for example, a closed loop, specifically, a polygon, and more specifically, a quadrilateral shape. The lines connecting the geometric centers of the first partitions T1 and the second partitions T2 form the curve, that is, the quadrilateral shape. According to such arrangement, under the same area of the power chip, compared with the case as shown in FIG. 6 where the first and second partitions are separately disposed, the case in the present embodiment the first and second partitions are disposed alternatively may reduce the distance between the geometrical centers of the partitions and the capacitors C, i.e. L2<L1. When the distance between the geometrical centers of the adjacent first and second partitions W1 is the same, the area of the commutation circuit loop correspondingly decreases, thus reducing the size of the commutation circuit loop, weakening the influence of the parasitic inductance, and improving efficiency of the power chip.

FIG. 9b is a schematic plan diagram showing an arrangement of the partitions in a power chip according to another embodiment of the present disclosure. In the present embodiment, the first partitions T1 and the second partitions T2 are disposed alternatively along another curve, for example, a closed loop, specifically, a polygon or an oval. More specifically, the lines connecting geometric centers of the adjacent first partition T1 and second partition T2 may form a hexagonal shape or a circle. It is worthwhile to mention that the first partition T1 and the second partition T2 can be disposed along any closed loop of any shapes, for example, polygons, circles, ovals, or any irregular closed loops. According to such arrangement in the present embodiment, the first and second partitions T1 and T2 are disposed alternatively for three times, however, the times that the first and second partitions are disposed alternatively may vary depending on actual requirements.

FIG. 9c is a schematic plan diagram showing an arrangement of the partitions in a power chip according to another embodiment of the present disclosure. In the present embodiment, the first partitions T1 and the second partitions T2 are disposed alternatively along a curve, for example, an open curve, more specifically, an arc or a polyline. According to such arrangement, the geometric centers of the first partitions T1 and the partitions T2 are disposed alternatively for twice (T1→T2→T1→T2) along the arc or the polyline. However, the times that the first and second partitions are disposed alternatively may vary depending on actual requirements. The first and second partitions may be any kind of shape, e.g. rectangles shown in FIG. 9a, hexagons in FIGS. 9b and 9c, etc.

The power chip of the present disclosure may further include driving circuit. As an embodiment, the power chip of the present disclosure may further include first driving circuits, configured to be closely adjacent to the first partitions to drive the first partitions; and second driving circuits, configured to be closely adjacent to the second partitions to drive the second partitions, wherein the first driving circuits and the second driving circuits are disposed alternatively to correspond to the alternative arrangement of the first and second partitions. The first driving circuits and the second driving circuits may be in the same layer or different layer with the first and second partitions.

FIG. 9d is a schematic plan diagram showing a power chip according to another embodiment of the present disclosure. Compared with the embodiment as shown in FIG. 9a, the power chip in the present embodiment further includes two first driving circuits 105 and two second driving circuit 106. The first driving circuits 105 are configured to turn on or turn off the first partitions T1. The second driving circuit 106 is configured to turn on or turn off the second partitions T2. In the embodiment, the first driving circuits 105 are closely adjacent to the first partitions T1 and may be configured in the same layer with the first partitions T1. The second driving circuits 106 are closely adjacent to the second partitions T2 and may be configured in the same layer with the second partitions T2. As an example, each of the partitions T1 and T2 is in a rectangular shape having four sides: a first side 1101, a second side 1102, a third side 1103 and a fourth side 1104, while two first driving circuits are at one side of corresponding one of two partitions T1, e.g. the first sides 1101 of partitions T1 and two second driving circuits are at the corresponding sides of partitions T2, e.g. the first sides of partitions T2. Actually, the first driving circuits may be at any side of T1 and the second driving circuits may be at any side of T2. For example, one of the first driving circuits may be at the first side 1101 of the upper left partition T1 and the other of the first driving circuits may be at the third side 1103 of the lower right partition T1 while one of the second driving circuits may be at the first side 1101 of upper right partition T2 and the other of the second driving circuits may be at the third side 1103 of the lower left partition T2. As another example, one of the first driving circuits may be at the second side 1102 of the upper left partition T1 and the other of the first driving circuits may be at the fourth side 1104 of the lower right partition T1 while one of the second driving circuits may be at the fourth side 1104 of upper right partition T2 and the other of the second driving circuits may be at the second side 1102 of the lower left partition T2. Thus the first and second driving circuits are all at the outer sides of T1 and T2. According to such arrangements, since the driving circuits are disposed to be close to the corresponding partitions, a size of driving circuits for turning on and off is reduced, and parasitic parameter of the driving circuits for turning on and off is reduced, and thereby reduces turn-off loss and achieves high efficiency performance under high frequency work condition. In the embodiment shown in FIG. 9d, the partitions T1 and T2 are alternatively disposed along a quadrilateral shape curve. The first driving circuits 105 and the second driving circuits 106 are also disposed alternatively along a quadrilateral shape curve.

As an embodiment, in the power chip of the present disclosure, the curve is a closed loop; and each of the first driving circuits and the second driving circuits may be disposed surrounding or partially surrounding the corresponding closely adjacent partition.

FIG. 9e and FIG. 9f are schematic perspective diagrams showing power chips according to another two embodiments of the present disclosure. Compared with the embodiment as shown in FIG. 9d, the first driving circuits 105 and the second driving circuits 106 in the present embodiment are disposed surrounding the partitions in FIG. 9e. As shown in FIG. 9e, the first driving circuits 105 are rectangle loops surrounding the corresponding first partitions T1 while the second driving circuits 106 are also rectangle loops surrounding the corresponding second partitions T2, which means each of the first and second driving circuits forms a close loop and locates at all sides of corresponding partitions. The first and second driving circuits 105 or 106 may be partially surrounding the corresponding partitions T1 or T2. For example, as shown in FIG. 9f, the first and second driving circuits 105 or 106 are L-shape and at two sides of the corresponding partitions T1 or T2. Specifically, one of the first driving circuits 105 is at the third and fourth sides of the upper left partition T1 and the other of the first driving circuits 105 is at the first and second sides of the lower right partition T1. One of the second driving circuits 106 are at the second and third sides of the upper right partition T2 and another one of the second driving circuits 106 is at the first and fourth sides of the lower left partition T2. The first and second driving circuits are all continuous. According to such arrangement, by connecting the first driving circuits 105 and the first partitions T1 and connecting the second driving circuits 106 and the second partitions T2, a size of the driving circuit is reduced, and parasitic parameter of the driving circuit is reduced, and thereby reduces switching loss and achieves high efficiency performance under high frequency work condition.

FIG. 10 is a schematic sectional diagram showing a power chip according to an embodiment. As shown in FIG. 10, the first and second partitions T1 and T2 are integrated in the wafer region 101. Specifically, the first and second partitions T1 and T2 may be formed by doping on the substrate P. The metal region 102 is provided above the first and second partitions T1 and T2. The metal region has two functions: connecting a plurality of the first partitions T1 in parallel, connecting a plurality of the second partitions T2 in parallel, and connecting the parallel-connected first partitions and parallel-connected second partitions in series, by respectively coupling with the first and second partitions T1 and T2; and achieving connection of the driving circuit.

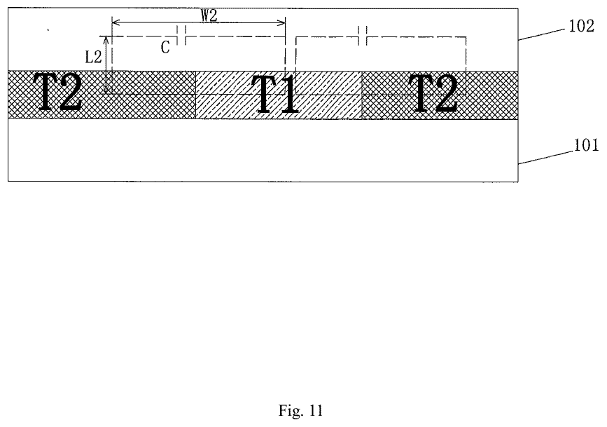

In order to further reduce the size of the commutation circuit loop, the capacitor C may be disposed in the metal region 102. FIG. 11 is a schematic sectional diagram showing a power chip in which a capacitor is disposed in the metal region according to an embodiment. As shown in FIG. 11, when the capacitor C is in the metal region, a distance L2 between the capacitor C and the geometrical centers of the first and second partitions T1 and T2 corresponds to thicknesses of the metal region 102, the first and second partitions T1 and T2. The distance L2 is far smaller than the distance L1 between the geometrical centers of the partitions and the capacitor as shown in FIG. 7. In the present embodiment, an area of the commutation circuit loop S3 is equal to W2*L2. Since L2<L1, the area S3 of the commutation circuit loop in the present embodiment is smaller than the area S2 of the commutation circuit loop in the embodiment as shown in FIG. 7. Therefore, the influence of the parasitic inductance is greatly weakened, and efficiency of the power chip is improved.

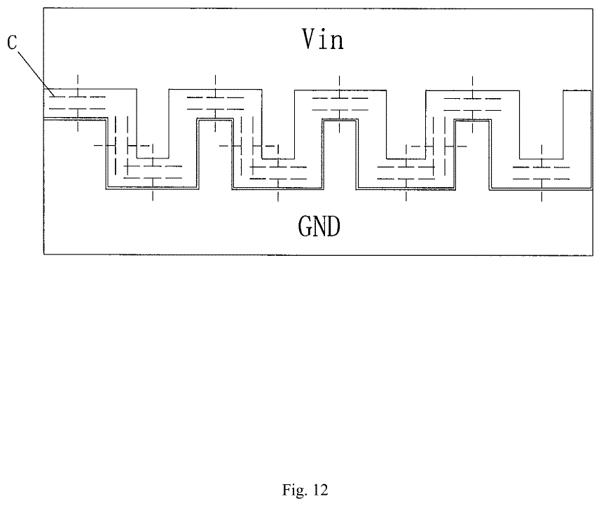

FIG. 12 is a schematic sectional diagram showing a metal region of a power chip. As shown in FIG. 12, the metal region 102 may include a first wiring layer M1 and a second wiring layer M2. The first wiring layer M1 is located above the first and second partitions T1 and T2, and forms a first pin GND through a metal lead. The second wiring layer M2 is located above the first wiring layer M1, and forms a second pin Vin through a metal lead. In the embodiment, the first wiring layer M1 and the second wiring layer M2 may be made of aluminium. Aluminium oxide in a honeycomb structure may be formed by anode oxidation between the first pin GND and the second pin Vin, such that a capacitor C is formed between the first pin GND and the second pin Vin. The first pin GND and the second pin Vin are coupled with the first and second partitions T1 and T2, respectively, such that the first partition T1, the second partition T2 and the capacitor C may form a closed commutation circuit loop. It should be noted that, the second wiring layer M2 is not limited to be located above the first wiring layer M1. The second wiring layer M2 may also be located below the first wiring layer M1.

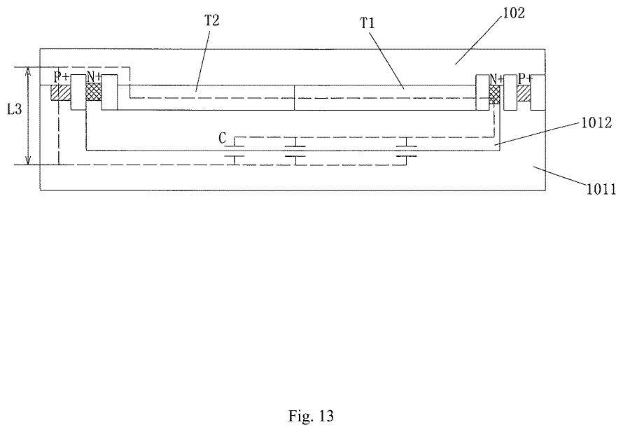

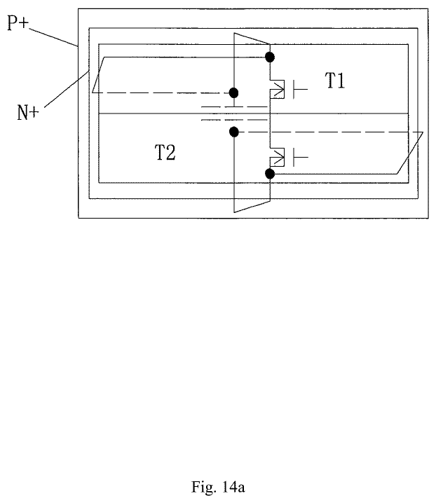

FIG. 13 is a schematic sectional diagram showing a power chip according to another embodiment. As shown in FIG. 13, the wafer region 101 includes a P type substrate layer 1011 and an N type insulating layer 1012. The N type insulating layer 1012 is disposed between the P type substrate layer 1011 and the first and second partitions T1 and T2. A junction capacitor is formed between the N type insulating layer 1012 and the P type substrate layer 1011, such that the capacitor C is disposed in the wafer region 101. The metal region 102 includes a first pin GND and the second pin Vin. In the present embodiment, the capacitor C has been disposed in the wafer region 101, thus it is unnecessary to conduct an anode oxidation treatment on the first pin GND and the second pin Vin. A wire electrode N⁺ is needed to connect the N type insulating layer 1012 with the second pin Vin. A wire electrode P⁺ is needed to connect the P type substrate layer 1011 with the first pin GND. In this way, two ends of the capacitor C formed in the wafer region 101 are respectively connected with the first and second partitions T1 and T2 through the metal region 102, thus forming a commutation circuit loop.

When the capacitor C is disposed in the metal region 101, a distance L3 between the capacitor C and the first and second partitions T1 and T2 corresponds to thicknesses of the wafer region 101, and the first and second partitions T1 and T2. The distance L3 is far smaller than the distance L1 between the geometrical centers of the partitions and the capacitor as shown in FIG. 7. In the present embodiment, an area of the commutation circuit loop S4 is equal to W2*L3. Since L3<L1, the area S4 of the commutation circuit loop in the present embodiment is smaller than the area S2 of the commutation circuit loop in the embodiment as shown in FIG. 7. Therefore, the influence of the parasitic inductance may be further weakened, and efficiency of the power chip may be improved.

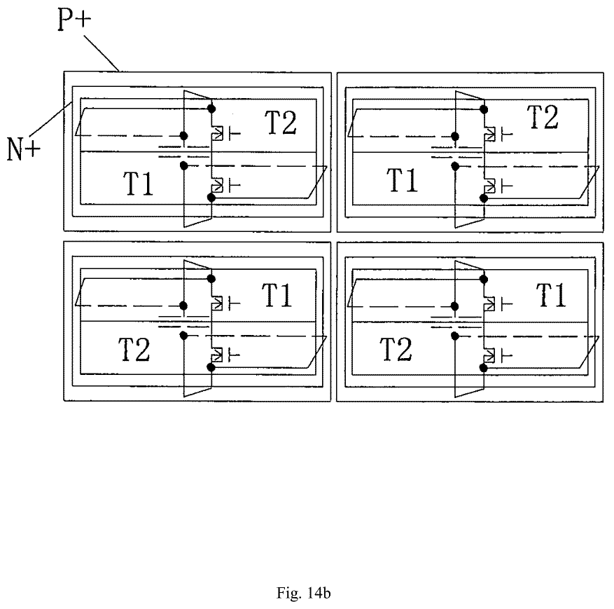

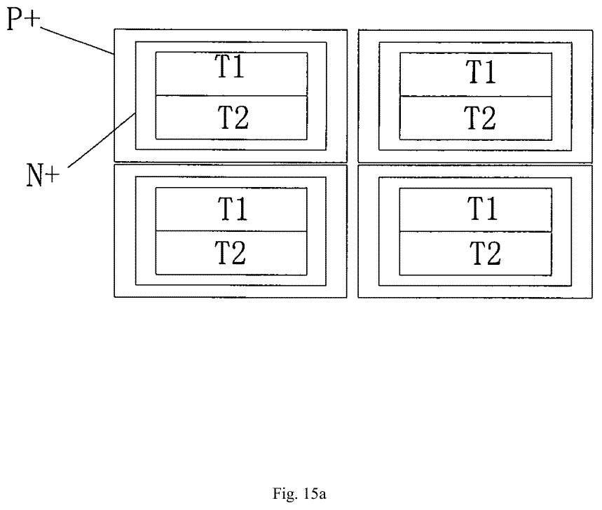

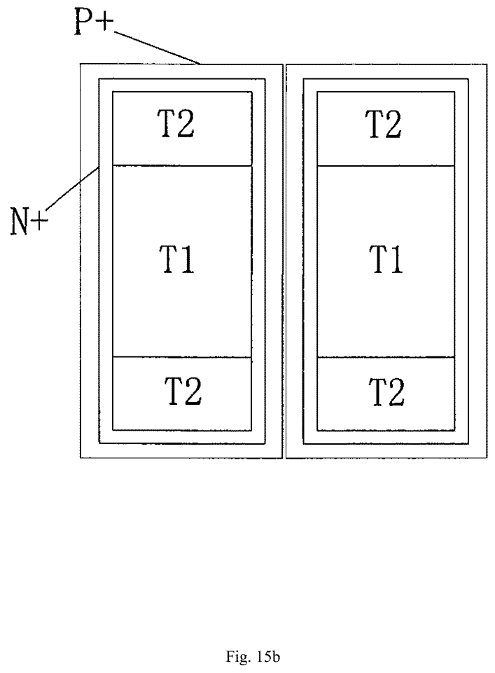

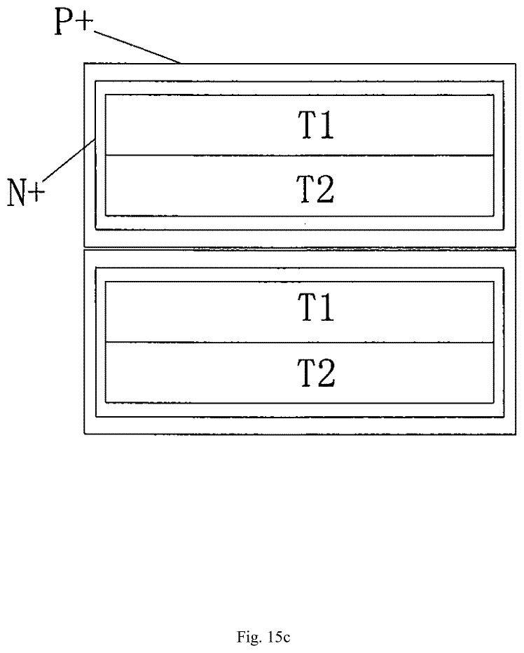

In addition, an arrangement manner of the wire electrodes N⁺ and P⁺ may influence the value of a parasitic resistance of the commutation circuit loop as shown in FIG. 13. The parasitic resistance of the commutation circuit loop mainly includes a parasitic resistance of the N type insulating layer, a parasitic resistance of the P type substrate layer, and a parasitic resistance of the metal region. The arrangement of the wire electrodes N⁺ and P⁺ usually presents a shape of closed rectangle frame on the top view, as shown in FIGS. 14a and 14b. Under the same area of the power chip, the more the chip are partitioned by the wire electrode, the more the rectangle frames of the wire electrodes will be, and the smaller the parasitic resistance of the commutation circuit loop will be. The reasons are as follows: four rectangle frames of the wire electrodes are partitioned in FIG. 14b on the basis of FIG. 14a, so the parasitic resistance of the commutation circuit loop of the rectangle frame of each wire electrode in FIG. 14b is one fourth of the parasitic resistance of the commutation circuit loop of the rectangle frame of the wire electrode in FIG. 14a. Since the four rectangle frames of the wire electrodes are connected in parallel through the upper metal region, a total parasitic resistance of the commutation circuit loop after being connected in parallel in FIG. 14b is one sixteenth of the parasitic resistance of the commutation circuit loop in FIG. 14a. Combining with the characteristic that the first and second partitions are arranged alternatively, the arrangement of the wire electrodes may include the following three manners: 1) as shown in FIG. 15a, the partitions are partitioned by the wire electrodes of the capacitor both along a first direction that the partitions are arranged alternatively and a second direction perpendicular to the first direction; 2) as shown in FIG. 15b, the partitions are partitioned by the wire electrodes of the capacitor along a second direction perpendicular to the first direction that the partitions are arranged alternatively; and 3) as shown in FIG. 15c, the partitions are partitioned by the wire electrodes of the input capacitor along the first direction that the partitions are arranged alternatively.

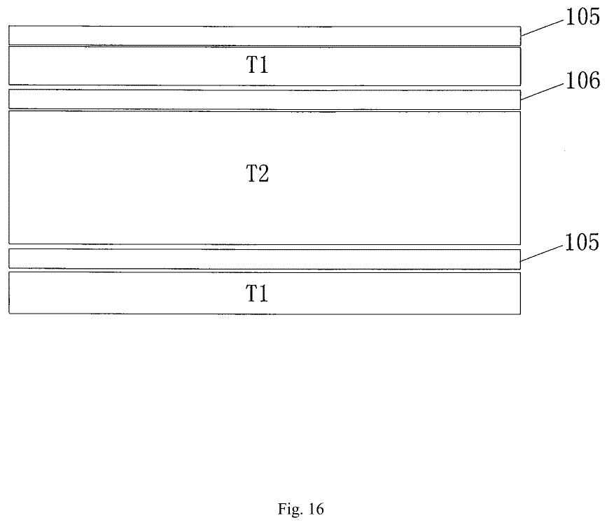

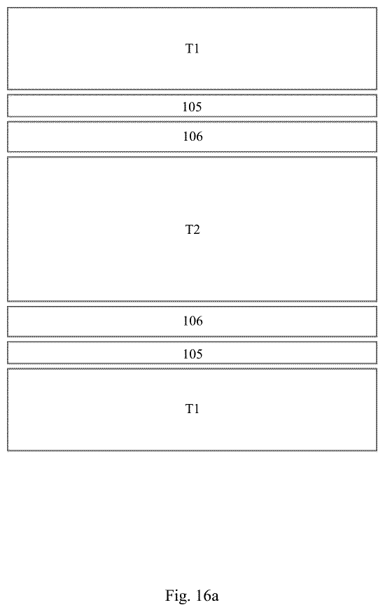

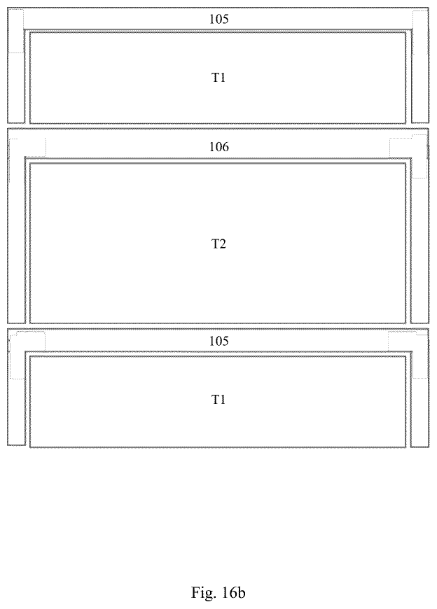

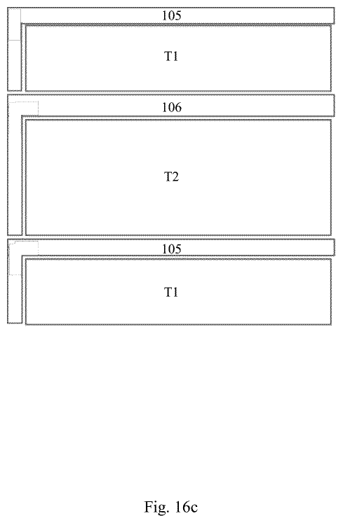

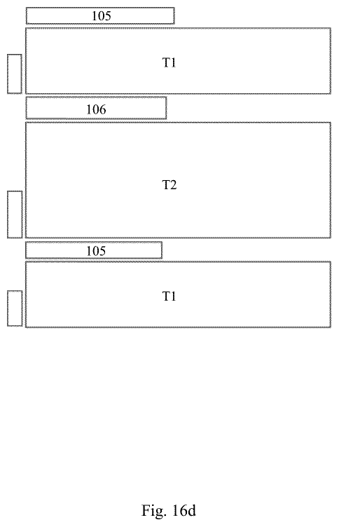

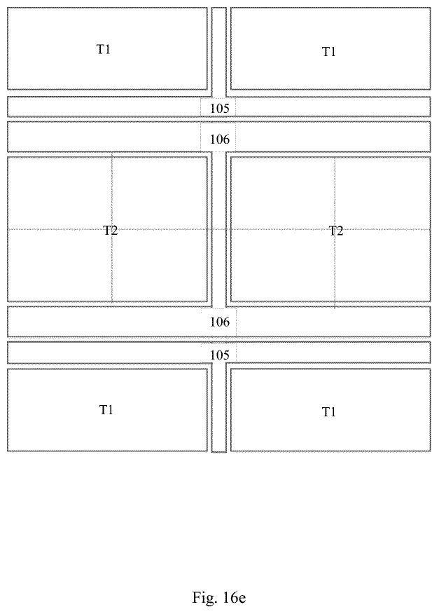

FIG. 16 is a schematic plan diagram showing a power chip according to another embodiment of the present disclosure. Compared with the above embodiment, the power chip in the present embodiment further includes the first driving circuits 105 and the second driving circuit 106. The first driving circuits 105 are configured to turn on or turn off the first partitions T1. The second driving circuit 106 is configured to turn on or turn off the second partition T2. In the embodiment, the first driving circuits 105 are closely adjacent to the first partitions T1 and may be configured in the same layer with the first partitions T1. The second driving circuit 106 is closely adjacent to the second partition T2 and may be configured in the same layer with the second partition T2. That is, the first driving circuits 105 and the second driving circuit 106 are arranged alternatively to correspond to the alternative arrangement of the first and second partitions T1 and T2. According to such arrangement, since the driving circuit is disposed to be close and parallel to the partition, a size of the driving circuit for turning on and off is reduced, and parasitic parameter of the driving circuit for turning on and off is reduced, and thereby reduces turn-off loss and achieves high efficiency performance under high frequency work condition.

FIG. 16a is a schematic plan diagram showing an arrangement of the power switches in a power chip according to another embodiment of the present disclosure. The power chip in the present embodiment further includes the first driving circuits 105 and the second driving circuits 106. The first driving circuits 105 are configured to turn on or turn off the first partitions T1. The second driving circuits 106 are configured to turn on or turn off the second partitions T2.

In this embodiment, the partitions T1 and T2 are both rectangle shapes with four sides. The first driving circuits are located at one side of corresponding partitions T1 while the second driving circuits are at two sides of partitions T2. That is to say, two second driving circuits are distributed along the two sides of the second partition T2. Thus at least one of the first driving circuits and at least one of the second driving circuits are disposed between one partition T1 and one partition T2. This arrangement is helpful to further reduce the parasitic inductance in such circumstance that the area of partition T2 may be larger than that of partition T1.

The first driving circuits 105 are closely adjacent to the first partitions T1 and may be configured in the same layer with the first partitions T1. The second driving circuits 106 are closely adjacent to the second partitions T2 and may be configured in the same layer with the second partitions T2. At least one of the first driving circuit 105 and at least one of the second driving circuit are between the partitions T1 and T2. Therefore the first driving circuits 105 and the second driving circuits 106 are also disposed alternatively to correspond to the alternative arrangement of the first and second partitions T1 and T2.

According to such arrangement, since the driving circuit is disposed to be close and parallel to the partitions, the distance of the driving circuit for turning on and off is reduced, and parasitic parameter of the driving circuit for turning on and off is reduced, and thereby reduces turn-off loss and achieves high efficiency performance under high frequency work condition.

As an embodiment, in the power chip of the present disclosure, the curve is the open curve; and each of the first driving circuits and the second driving circuits may be disposed surrounding or partially surrounding the corresponding closely adjacent partition.

FIG. 16b is schematic perspective diagrams showing power chips of the present disclosure. Compared with the embodiment as shown in FIG. 16a, the first driving circuits 105 and the second driving circuit 106 in the present embodiment are disposed partially surrounding the corresponding partitions. As shown in FIG. 16b, partitions T1 and T2 are all rectangle shapes with four sides. The first and second driving circuits are at three sides of the corresponding partitions. The first and second driving circuits partially surrounding the corresponding partitions T1 and T2 means that they are located at at least two sides of the corresponding partitions and do not form a close loop. FIG. 16c and FIG. 16d show another two examples wherein the first and second driving circuits partially surround the corresponding partitions T1 and T2. In FIG. 16c, the first driving circuits partially surround the corresponding partitions T1, wherein the first driving circuits are continuous. So do the second driving circuits. The difference between FIGS. 16c and 16d is that both of the first and second driving circuits are not continuous but separated into lots of parts to locate at different sides of the corresponding partitions. Even more, the first driving circuits may be continuous and the second driving circuits may be separated, or the second driving circuits may be continuous and the first driving circuits may be separated. According to such arrangement, by connecting the first driving circuit 105 and the first partition T1 and connecting the second driving circuit 106 and the second partition T2, the distance between the partition and the corresponding driving circuit is reduced, the parasitic parameter of the driving circuit is reduced, and thereby reduces switching loss and achieves high efficiency performance under high frequency work condition.

FIG. 16e is a schematic perspective diagram showing power chips of the present disclosure. Compared with the embodiment as shown in FIG. 16b, there are at least six partitions with four partitions T1 and two partitions T2. As a cell, two partitions T1 and one partition T2 are arranged alternatively along the Y direction. This cell is copied along the X direction. The first driving circuits 105 and the second driving circuits 106 in the present embodiment may be disposed surrounding or partially surrounding the corresponding partitions. In this embodiment, the driving circuits all partially surround the partitions respectively. As shown in FIG. 16e, a first driving circuit is T-shape and located at two sides of the two partitions T1, wherein the two partitions T1 are adjacent to each other along the X direction and share at least part of one of the first driving circuit. While an H-shape second driving circuit partially surrounds two partitions T2 along the X direction. According to such arrangement, by connecting the first driving circuits 105 and the first partitions T1 and connecting the second driving circuit 106 and the second partition T2, the distance between different parts of the power switch and the corresponding driving circuit is more uniform. The switching speed of different parts of the power switch is more uniform, and thereby reduces switching loss and achieves high efficiency performance under high frequency work condition.

In general, the shape of the partitions in any one of the embodiments is not limited, which means it can be any kind of shape, such as rectangle, triangle, hexagon, polygon, oval, etc. The shape of the first and second driving circuits is not limited. The numbers of the partitions in any one of the embodiment is not limited too, which means there may be less or more partitions T1 and T2 alternatively arranged along a curve. The numbers of the first and second driving circuits are not limited too. As an example, the first and second driving circuits may also be alternatively arranged along a curve.

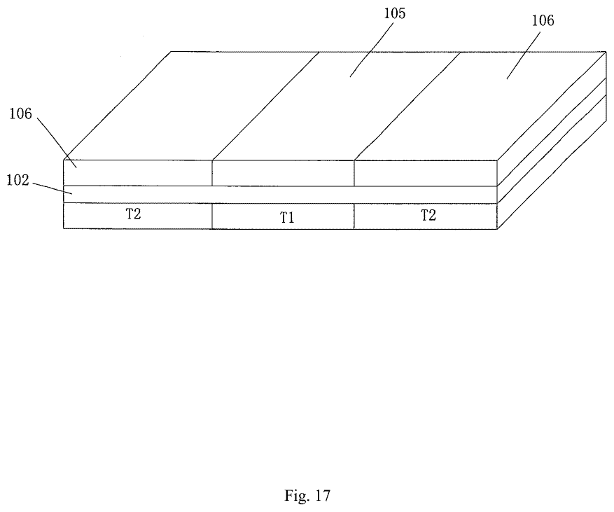

FIG. 17 is a schematic perspective diagram showing a power chip according to another embodiment of the present disclosure. Compared with the embodiment as shown in FIG. 16, the first driving circuit 105 and the second driving circuit 106 in the present embodiment are not disposed in the same layer with the partition. On the contrary, the first driving circuit 105 and the second driving circuit 106 are disposed above the metal region 102. Furthermore, the first driving circuit 105 and the second driving circuit 106 are disposed directly above the corresponding first partition T1 and the corresponding second partition T2 thereof. By connecting the first driving circuit 105 and the first partition T1 and connecting the second driving circuit 106 and the second partition T2 through the metal region 102, a size of the turn-off driving circuit is reduced, and parasitic parameter of the turn-off driving circuit is reduced, and thereby reduces turn-off loss and achieves high efficiency performance under high frequency work condition.

In the above embodiments, the first partition T1 includes the first terminal, the second terminal and the control terminal. The second partition T2 includes the first terminal, the second terminal and the control terminal. For example, the first and second partitions T1 and T2 may be MOS (Metal Oxide Semiconductor) transistors, including a source electrode, a drain electrode and a gate electrode. However, a type of the first and second power switches in the present disclosure is not limited thereto. Both the first and second power switches SS1 and SS2 are lateral type power devices. For lateral type, both the source electrode and the drain electrode of the first power device SS1 are disposed on an upper surface of the first power device SS1 so as to connect with the first pin GND and the second pin Vin in the metal region 102 and closely arrange the capacitor, to reduce the size of the commutation circuit loop.

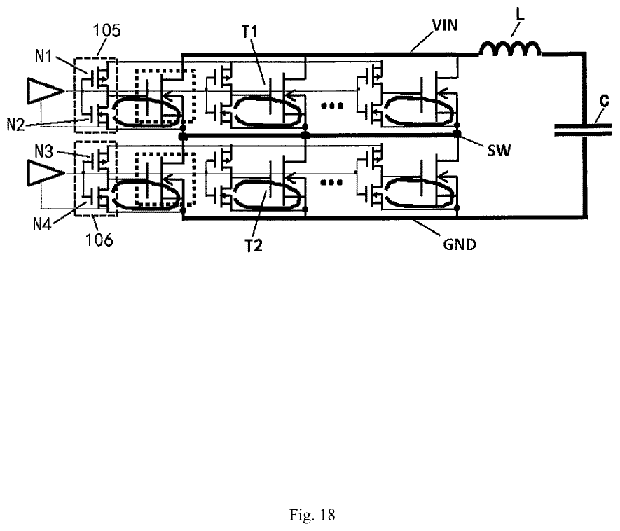

FIG. 18 shows a schematic circuit diagram of a driving circuit in a power chip according to an embodiment of the present disclosure. As shown in FIG. 18, the first driving circuit 105 includes a third switch N1 and a fourth switch N2. For example, the third switch N1 and the fourth switch N2 may be MOS transistors. However, the present disclosure is not limited thereto. A source electrode of the third switch N1 is connected to a drain electrode of the fourth switch N2 and a gate electrode of the first partition T1. A source electrode of the fourth switch N2 is connected to a source electrode of the first partition T1. The second driving circuit 106 includes a fifth switch N3 and a sixth switch N4. For example, the fifth switch N3 and the sixth switch N4 may be MOS transistors. However, the present disclosure is not limited thereto. A source electrode of the fifth switch N3 is connected to a drain electrode of the sixth switch N4 and a gate electrode of the second partition T2. A source electrode of the sixth switch N4 is connected to a source electrode of the second partition T2.

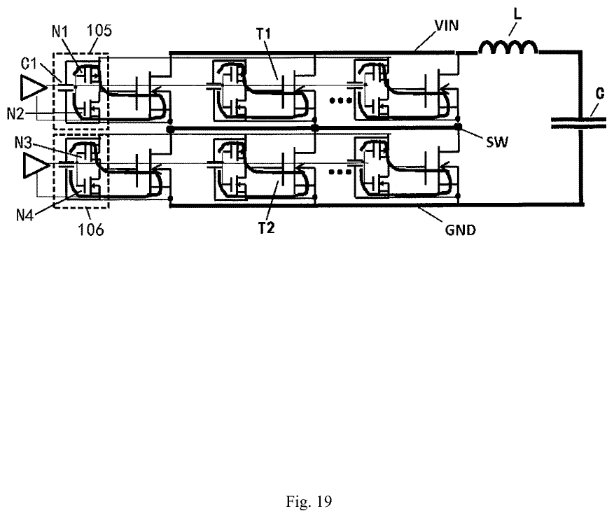

The first driving circuit 105 and the second driving circuit 106 as shown in FIGS. 16 and 17 may further include a driving capacitor, and a schematic circuit diagram thereof is shown in FIG. 19.

FIG. 19 is a schematic diagram showing a driving circuit in a power chip according to an embodiment of the present disclosure. Compared with the first driving circuit and the second driving circuit as shown in FIG. 18, a driving capacitor C1 is added in the driving circuit in the present embodiment. One terminal of the driving capacitor C1 in the first driving circuit 105 is connected to the drain electrode of the third switch N1, and the other terminal of the driving capacitor C1 in the first driving circuit 105 is connected to the source electrode of the fourth switch N2. Similarly, one terminal of the driving capacitor C1 in the second driving circuit 106 is connected to the drain electrode of the fifth switch N3, and the other terminal of the driving capacitor C1 in the second driving circuit 106 is connected to the source electrode of the sixth switch N4. In the present embodiment, the driving capacitor is disposed in the driving circuit, so that the driving circuit is closer to the partition, thus reducing the size of the turn-on driving circuit.

A bridge circuit including a first partition T1, a second partition T2 and a capacitor C is also provided in an embodiment of the present disclosure. For example, the first partitions T1 are connected in parallel to form a first bridge arm. The first bridge arm has a first terminal and a second terminal. The second partitions T2 are connected in parallel to form a second bridge arm. The second bridge arm is connected in series with the first bridge arm and has a first terminal and a second terminal. The first terminal of the second bridge arm is electrically coupled to the second terminal of the first bridge arm. The capacitor C has a first end and a second end, the first end of the capacitor C is coupled to the first terminal of the first bridge arm, and the second end of the capacitor C is coupled to the second terminal of the second bridge arm. In the embodiment, the first and second partitions T1 and T2 are integrated in the power chip as shown in the above embodiments. Furthermore, the first and second partitions T1 and T2 inside the power chip are arranged alternatively along at least one direction as shown in the above embodiments. In addition, in other embodiments, there is a single first partition T1, and there are two or more second partition T2. Otherwise, there are two or more first partition T1, and there is a single second partition T2. The arrangement manner of the first and second partitions T1 and T2 has been illustrated in detail in the above embodiments of the power chip, which will not be repeated herein.

In the present embodiment, the first and second partitions inside the power chip are arranged alternatively, which may reduce parasitic inductance value of an equivalent commutation circuit loop of a Buck circuit, thereby ensuring high efficiency and high power density of the power supply.

Although the above implementation has disclosed specific embodiments of the present disclosure, it does not limit the present disclosure. Those skilled in the art may make various variation and modification without departing from the scope and sprit of the present disclosure. The protection scope of the present disclosure is subject to the scope defined by the claims.

What is claimed is:

1. A power chip, comprising:
a metal region;
a wafer region; comprising:
a substrate;
at least one first partition, forming a first power switch; and
at least one second partition, forming a second power switch,
wherein the at least one first partition and the at least one second partition are formed by doping on the substrate; and
wherein the first power switch and the second power switch are electrically connected, a total number of the at least one first partition and the at least one second partition is not less than 3, and the at least one first partition and the at least one second partition are disposed alternatively along a curve.

2. The power chip according to claim 1, wherein
the first power switch has a first terminal, a second terminal and a control terminal,
the second power switch has a first terminal, a second terminal and a control terminal, and
that the first power switch is electrically connected to the second power switch, comprises any one of:
that the first terminal of the first power switch is electrically connected to the first terminal of the second power switch,
that the second terminal of the first power switch is electrically connected to the second terminal of the second power switch, and
that the second terminal of the first power switch is electrically connected to the first terminal of the second power switch.

3. The power chip according to claim 1, wherein
the curve is one of: a closed loop and an open curve,
the close loop is any one of: a polygon and an oval; and
the open curve is any one of: a straight line, a polyline and an arc.

4. The power chip according to claim 1, wherein the second terminal of the first power switch is electrically connected to the first terminal of the second power switch, the power chip further comprising:
a capacitor, disposed in the metal region, wherein the capacitor, the first power switch and the second power switch form a commutation circuit loop.

5. The power chip according to claim 4, wherein the metal region comprises:
a first wiring layer, located above the wafer region, and configured to form a first pin through a metal lead; and
a second wiring layer, located above or below the first wiring layer, and configured to form a second pin through a metal lead,
wherein the capacitor is formed between the first wiring layer and the second wiring layer by an anode oxidation process.

6. The power chip according to claim 2, wherein the second terminal of the first power switch is electrically connected to the first terminal of the second power switch, the power chip further comprising:
a capacitor, disposed in the wafer region, wherein the capacitor, the first power switch and the second power switch form a commutation circuit loop.

7. The power chip according to claim 6, wherein the wafer region comprises:
a N type insulating layer, disposed between a P type substrate layer and the at least one first partition and the at least one second partition, and two ends of a junction capacitor between the N type insulating layer and the P type substrate layer are respectively coupled to a first pin and a second pin through metal leads.

8. The power chip according to claim 7, wherein
the N type insulating layer is coupled to the second pin through a wire electrode N+, and the P type substrate layer is coupled to the first pin through a wire electrode P+.

9. The power chip according to claim 3, further comprising:
at least one first driving circuit, wherein one of the at least one first driving circuit is configured to be closely adjacent to one of the at least one first partition; and
at least one second driving circuit, wherein one of the at least one second driving circuit is configured to be closely adjacent to one of the at least one second partition.

10. The power chip according to claim 9, further comprising:
at least one first driving circuit, wherein each of the at least one first driving circuit is configured to be closely adjacent to a corresponding one of the at least one first partition; and
at least one second driving circuit, wherein each of the at least one second driving circuit is configured to be closely adjacent to a corresponding one of the at least one second partition,
wherein the first driving circuit and the second driving circuit are disposed alternatively to correspond to the alternative arrangement of the first and second partitions.

11. The power chip according to claim 9, wherein one of the at least one first driving circuit is disposed surrounding or partially surrounding the one of the at least one first partition and the second driving circuits is disposed surrounding or partially surrounding the one of the at least one second partition.

12. The power chip according to claim 11, wherein each of the at least one first driving circuit is disposed surrounding or partially surrounding the corresponding one of the at least one first partition and the second driving circuits is disposed surrounding or partially surrounding the corresponding one of the at least one second partition.

13. The power chip according to claim 12, wherein a shape of each of the at least one first partition and the at least one second partition is rectangle, the curve is a rectangle, and the numbers of the at least one first partition and the at least one second partition are both two.

14. The power chip according to claim 10, wherein a shape of each of the at least one first partition and the at least one second partition is the same type of polygon, the at least one first driving circuit and the at least one second driving circuit are disposed at one side of the at least one first partition and one side of the at least one second partition respectively.

15. The power chip according to claim 10, wherein a shape of each of the at least one first partition and the at least one second partition is rectangle, each of the at least one first partition and the at least one second partition has a first side, a second side, a third side and a fourth side, and the first side, the second side, the third side and the fourth side of the at least one first partition are corresponding to the first side, the second side, the third side and the fourth side of the at least one second partition respectively.

16. The power chip according to claim 15, wherein the numbers of the at least one first partition and the at least one second partition are both two, the numbers of the at least one first driving circuit and the at least one second driving circuit are both two, and the curve is a rectangle.

17. The power chip according to claim 16, wherein the at least one first driving circuit and the at least one second driving circuit are disposed at one side of the at least one first partition and one side of the at least one second partition respectively.

18. The power chip according to claim 17, wherein one of the at least one first driving circuit is positioned at the first side of the corresponding one of the at least one first partition, the other one of the at least one first driving circuit is positioned at the third side of the corresponding one of the at least one first partition, one of the at least one second driving circuit is positioned at the first side of the corresponding one of the at least one second partition, and the other one of the at least one second driving circuit is positioned at the third side of the corresponding one of the at least one second partition.

19. The power chip according to claim 17, wherein one of the at least one first driving circuit is positioned at the fourth side of the corresponding one of the at least one first partition, the other one of the at least one first driving circuit is positioned at the second side of the corresponding one of the at least one first partition, one of the at least one second driving circuit is positioned at the second side of the corresponding one of the at least one second partition, and the other one of the at least one second driving circuit is positioned at the fourth side of the corresponding one of the at least one second partition.

20. The power chip according to claim 16, wherein each of the at least one first driving circuit is positioned at two adjacent sides of the corresponding one of the at least one first partition, and each of the at least one second driving circuit is positioned at two adjacent sides of the corresponding one of the at least one second partition.

21. The power chip according to claim 20, wherein one of the at least one first driving circuit is positioned at the first side and the second side of the corresponding one of the at least one first partition, one of the at least one first driving circuit is positioned at the third side and the fourth side of the corresponding one of the at least one first partition, one of the at least one second driving circuit is positioned at the second side and the third side of the corresponding one of the at least one second partition, and one of the at least one second driving circuit is positioned at the first side and the fourth side of the corresponding one of the at least one second partition.

22. The power chip according to claim 16, wherein each of the at least one first driving circuit is positioned at two opposite sides of the corresponding one of the at least one first partition, and each of the at least one second driving circuit is positioned at two opposite sides of the corresponding one of the at least one second partition.

23. The power chip according to claim 15, wherein one of the at least one first driving circuit is positioned at the third side of the corresponding one of the at least one first partition, one of the at least one first driving circuit is positioned at the first side of the corresponding one of the at least one first partition, each of the at least one second driving circuit is positioned at the first side and the third side of the corresponding one of the at least one second partition.

24. The power chip according to claim 15, wherein each of the at least one first driving circuit is positioned at three sides of the corresponding one of the at least one first partition, and each of the at least one second driving circuit is positioned at three sides of the corresponding one of the at least one second partition.

25. The power chip according to claim 15, wherein each of the at least one first driving circuit is disposed partially surrounding the corresponding one of the at least one first partition and the second driving circuits is disposed partially surrounding the corresponding one of the at least one second partition.

26. The power chip according to claim 25, wherein each of the at least one first driving circuit is disposed at two adjacent sides of the corresponding one of the at least one first partition and the second driving circuits is disposed at two adjacent sides of the corresponding one of the at least one second partition.

27. The power chip according to claim 26, wherein the two adjacent sides are continuous.

28. The power chip according to claim 27, wherein the two adjacent sides are not continuous.

29. The power chip according to claim 15, wherein a first one of the at least one first partition, a first one of the at least one second partition and a second one of the at least one first partition are arranged along a Y direction, a third one of the at least one first partition, a second one of the at least one second partition and a fourth one of the at least one first partition are arranged along a Y direction, the first one of at least one first partition and the third one of at least one first partition are arranged along a X direction, the first one of at least one second partition and the second one of at least one second partition are arranged along a X direction, the second one of at least one first partition and the fourth one of at least one first partition are arranged along a X direction, one of the at least one first driving circuit is T-shape and located at two sides of the first one of the at least one first partition and the third one of the at least one first partition, another one of the at least one first driving circuit is T-shape and located at two sides of the second one of the at least one first partition and the fourth one of the at least one first partition, and one of the at least second driving circuit is H-shape and partially surrounds the first one of the at least one second partition and the second one of the at least one second partition.

30. The power chip according to claim 9, wherein both the first driving circuit and the second driving circuit further comprise a driving capacitor.
